(19) United States
(12) Patent Application Publication
(10) Pub. No.: US 2013/0192886 A1
(43) Pub. Date: Aug. 1, 2013

(54) THERMOSETTING FILLING RESIN COMPOSITION

(71) Applicant: Arata Endo, Saitama-ken (JP)

(72) Inventor: Arata Endo, Saitama-ken (JP)

(73) Assignee: TAIYO HOLDINGS CO., LTD., Tokyo (JP)

(21) Appl. No.: 13/819,785

(22) PCT Filed: Sep. 27, 2011
(86) PCT No.: PCT/JP2011/005426

§ 371 Date: Apr. 1, 2013

(30) Foreign Application Priority Data
Sep. 27, 2010 (JP) 2010-215525

(51) Int. Cl. C08K 5/09; H05K 1/03

(52) U.S. Cl. CPC C08K 5/09; H05K 1/032
USPC 174/258; 523/456

(57) ABSTRACT

Provided is a heat-curable resin filler in which the deterioration in thixotropic properties over time can be prevented and which has excellent shape retaining properties after being filled in hole parts in a printed wiring board and being cured and also has excellent abradability. The heat-curable resin filler comprises an epoxy resin, an epoxy resin curing agent, an inorganic filler and a fatty acid represented by the following general formula: (R₁COO)n-R₂ (wherein the substituent R₁ represents a hydrocarbon group having 5 or more carbon atoms; the substituent R₂ represents a hydrogen atom, an metal alkoxide group or a metal atom; and n is 1 to 4).

### TECHNICAL FIELD

The present invention relates to a thermosetting filling resin composition which is used in, for example, hole filling for printed wiring boards and the like.

### BACKGROUND ART

In recent years, along with the miniaturization and functional improvement of electronic instruments, there is a demand for micronization of the pattern of printed wiring boards, reduction of the packaging area, and compactization of component packaging. Accordingly, use is made of a multilayer substrate such as a build-up wiring board, in which insulating layers and conductor circuits are sequentially formed on a two-sided substrate provided with through-holes or on a core material, and connection is achieved between layers with via-holes or the like so as to have the substrate multilayered. Further, the multilayer substrate is subjected to area array packaging such as BGA (ball grid array) or LGA (land grid array).

In such a printed wiring board, an electroconductive layer is formed on the surface and the inner walls of hole parts such as penetrating holes called through-holes or via holes, and a resin such as a thermosetting resin is filled in the hole parts by printing or the like. At this time, since the resin is filled such that the resin slightly protrudes from the hole parts, the protruded parts are flattened or removed after curing, by polishing or the like. Furthermore, the electroconductive layer of the surface is subjected to patterning (see, for example, Patent Literature 1).

### CITATION LIST

### Patent Literature

PLT1: Japanese Patent Application Laid-Open No. 10-75027

### SUMMARY OF THE INVENTION

### Technical Problem

As such, as the resin composition that fills in the hole parts of a printed wiring board and protrudes from the hole parts causes sagging at the surface of the printed wiring board, there is a problem that such sagging affects the electrical characteristics and reliability of the printed wiring board, causing planing of the electroconductive layer at the time of polishing, difficulty in the formation of a flat cover plating caused by the occurrence of depression on the through-holes, and patterning failure caused by the occurrence of resin residue on the electroconductive layer.

The present invention was achieved in view of such circumstances, and it is an object of the invention to provide a thermosetting filling resin composition in which deterioration of thixotropic properties overtime can be suppressed, and which has excellent shape retaining properties after filling in hole parts in a printed wiring board and curing, and has excellent abradability.

### Solution to Problem

To solve the problems, a thermosetting filling resin composition according to an aspect of the present invention includes an epoxy resin, an epoxy resin curing agent, an inorganic filler, and a fatty acid represented by formula: (R₁COO)n-R₂ where substituent R₁ represents a hydrocarbon having 5 or more carbon atoms; substituent R₂ represents hydrogen, a metal alkoxide, or a metal; and n=1 to 4.

As this thermosetting filling resin composition has such a constitution, thixotropic properties are imparted, and also, deterioration over time is suppressed, so that excellent shape retaining properties after filling in hole parts in a printed wiring board and curing, and excellent abradability can be obtained.

In the thermosetting filling resin composition according to the aspect of the present invention, the fatty acid is preferably incorporated such that the inorganic filler is surface-treated with the fatty acid. With such a constitution, thixotropic properties can be imparted more effectively.

In the thermosetting filling resin composition according to the aspect of the present invention, the fatty acid is preferably incorporated in an amount of 0.1 parts to 2 parts by mass relative to 100 parts by mass of the inorganic filler. With a constitution, good thixotropic properties can be exhibited.

Preferably, the thermosetting filling resin composition includes a silane-based coupling agent.

With such a constitution, the adhesiveness between the inorganic filler and the epoxy resin is enhanced, so that the occurrence of cracks in a cured product thereof can be suppressed.

Preferably, a printed wiring board according to another aspect of the present invention includes hole parts that are filled with a cured product of the thermosetting filling resin composition.

With such a constitution, good electrical characteristics and reliability can be obtained.

### Advantageous Effects of Invention

When the thermosetting filling resin composition according to the aspect of the present invention is used, deterioration of thixotropic properties overtime can be suppressed, and excellent shape retaining properties after filling in hole parts in a printed wiring board and curing, and excellent abradability can be obtained.

### BRIEF DESCRIPTION OF THE DRAWINGS

FIG. 1 is a production process diagram for a substrate for evaluation.

FIG. 2 is a cross-sectional microscopic photograph of a hole part according to Example 2.

FIG. 3 is a cross-sectional microscopic photograph of a hole part according to Example 3.

FIG. 4 is a cross-sectional microscopic photograph of a hole part according to Example 4.

FIG. 5 is a cross-sectional microscopic photograph of a hole part according to Comparative Example 1.

FIG. 6 is a cross-sectional microscopic photograph of a hole part according to Comparative Example 2.

FIG. 7A is a cross-sectional microscopic photograph of a hole part according to Comparative Example 3.

FIG. 7B is a partially magnified photograph of FIG. 7A.

FIG. 8 is a production process diagram for a substrate for evaluation.

### DESCRIPTION OF EMBODIMENTS

The inventors of the present invention conducted a thorough investigation with regard to the problems described above, and as a result, the inventors found that when an epoxy resin is mixed with a fatty acid having low compatibility with this epoxy resin, good thixotropic properties can be obtained, and also deterioration of thixotropic properties over time can be suppressed. Thus, the inventors finally completed the present invention.

That is, the thermosetting filling resin composition of the present invention contains an epoxy resin, an epoxy resin curing agent, an inorganic filler, and a fatty acid represented by formula: (R₁COO)n-R₂ (wherein substituent R₁ represents a hydrocarbon having 5 or more carbon atoms; substituent R₂ represents hydrogen, a metal alkoxide, or a metal; and n=1 to 4).

Conventionally, in order to enhance the dispersibility of an inorganic filler in a resin, a dispersant having high compatibility with a resin, for example, generally, a silane coupling agent is used for an epoxy resin, and a fatty acid such as stearic acid is used for a paraffin/olefin-based resin.

In contrast to this, in the present invention, by adding a fatty acid having low compatibility that is usually not added to an epoxy resin, good thixotropic properties can be imparted, and also, deterioration of thixotropic properties over time can be suppressed. Therefore, excellent shape retaining properties by which the occurrence of sagging after filling in hole parts in a printed wiring board or the like is suppressed, can be obtained. Furthermore, since the occurrence of sagging is suppressed, the occurrence of depressions on the hole parts after curing as caused by sagging, or the generation of a resin residue on the electroconductive layer is suppressed, and thereby, excellent abradability can be obtained. Accordingly, a printed wiring board having high reliability such as electrical characteristics can be provided.

Hereinafter, embodiments of the present invention will be described in detail.

The epoxy resin that constitutes the thermosetting filling resin composition of the present embodiment may be any epoxy resin having two or more epoxy groups in one molecule, and known epoxy resins can be used. Examples thereof include compounds having two or more epoxy groups in one molecule, such as a bisphenol A type epoxy resin, a bisphenol S type epoxy resin, a dinaphthol type epoxy resin, a bisphenol F type epoxy resin, a phenol-novolac type epoxy resin, a cresol-novolac type epoxy resin, an alicyclic epoxy resin, diglycidyl ether of propylene glycol or polypropylene glycol, polytetramethylene glycol diglycidyl ether, glycerol polyglycidyl ether, trimethylolpropane polyglycidyl ether, phenyl-1,3-diglycidyl ether, biphenyl-4,4′-diglycidyl ether, 1,6-hexanediol diglycidyl ether, diglycidyl ether of ethylene glycol or propylene glycol, sorbitol polyglycidyl ether, sorbitan polyglycidyl ether, tris(2,3-epoxypropyl) isocyanurate, and triglycidyl tris(2-hydroxyethyl) isocyanurate; and amine type epoxy resins such as tetraglycidyl aminodiphenylmethane, tetraglycidyl methaxylylenediamine, triglycidyl para-aminophenol, diglycidyl aniline, and diglycidyl ortho-toluidine.

Examples of commercially available products thereof include 828 manufactured by Mitsubishi Chemical Corp. as a Bis-A type liquid epoxy resin; 807 manufactured by Mitsubishi Chemical Corp. as a Bis-F type liquid epoxy resin; and jER-630 manufactured by Mitsubishi Chemical Corp. and ELM-100 manufactured by Sumitomo Chemical Co., Ltd. as amine type liquid epoxy resins (para-aminophenol type liquid epoxies).

Among these, para-aminophenol type liquid epoxies that have low viscosity, can increase the filling amount of the filler when the resin is prepared into a paste, and contain a benzene ring which is a heat-resistant backbone structure, and the like are particularly preferred. These can be used singly, or two or more kinds can be used in combination.

The epoxy resin curing agent is used in order to cure the epoxy resin. Examples of such an epoxy resin curing agent include tertiary amines, tertiary amine salts, quaternary onium salts, tertiary phosphines, crown ether complexes, and phosphonium ylides. These can be used singly, or two or more kinds can be used in combination.

Among these, preferred examples include amines such as imidazoles, azine compounds of imidazole, isocyanurates of imidazole, imidazole hydroxymethyl form, dicyandiamide and derivatives thereof, melamine and derivatives thereof, diaminomaleonitrile and derivatives thereof, diethylenetriamine, triethylenetetramine, tetraethylenepentamine, bis(hexamethylene)triamine, triethanolamine, diaminodiphenylmethane, and organic acid dihydrazides; and organic phosphine compounds such as 1,8-diazabicyclo[5,4,0]undecene-7, 3,9-bis(3-aminopropyl)-2,4,8,10-tetraoxaspiro[5,5]undecane, triphenylphosphine, tricyclohexylphosphine, tributylphosphine, and methyldiphenylphosphine.

Examples of commercially available products thereof include 2E4MZ, C11Z, C17Z and 2PZ manufactured by Shikoku Chemicals Corp. as imidazoles; 2MZ-A and 2E4MZ-A manufactured by Shikoku Chemicals Corp. as azine compounds of imidazole; 2MZ-OK and 2PZ-OK manufactured by Shikoku Chemicals Corp. as isocyanurates of imidazole; DBU manufactured by San-Apro, Ltd. as 1,8-diazabicyclo[5,4,0]undecene-7; and ATU manufactured by Ajinomoto Co., Inc. as 3,9-bis(3-aminopropyl)-2,4,8,10-tetraoxaspiro[5,5]undecane.

Among these, the imidazole in particular is suitable because the imidazole has excellent heat resistance and chemical resistance in a cured product of an epoxy resin, and since hydrophobicity is obtained, moisture absorption can be suppressed. Furthermore, dicyandiamide, melamine; guanamine and derivatives thereof such as acetoguanamine, benzoguanamine, and 3,9-bis[2-(3,5-diamino-2,4,6-triazaphenyl)ethyl]-2,4,8,10-tetraoxaspiro[5,5]undecane; and organic acid salts or epoxy adducts thereof are known to have adhesiveness to copper or antirust properties. Furthermore, since these compounds work as epoxy resin curing agents, and can also contribute to the prevention of discoloration of copper in printed wiring boards, these compounds can be suitably used.

Regarding the mixing proportion of such an epoxy resin curing agent, it is sufficient to employ a conventional proportion, and for example, the mixing proportion is appropriately 0.1 parts to 10 parts by mass relative to 100 parts by mass of the epoxy resin.

The inorganic filler is used for the relaxation of stress caused by curing shrinkage or the adjustment of the coefficient of linear expansion. Regarding such an inorganic filler, those known inorganic fillers that are used in conventional resin compositions can be used. Specific examples thereof include non-metallic fillers such as silica, barium sulfate, calcium carbonate, silicon nitride, aluminum nitride, boron nitride, alumina, magnesium oxide, aluminum hydroxide, magnesium hydroxide, titanium oxide, mica, talc, and organic bentonite; and metallic fillers such as copper, gold, silver, palladium, and silicon. These can be used singly, or two or more kinds can be used in combination.

Among these, silica and calcium carbonate, both of which exhibit low hygroscopicity and low volume expandability, are suitably used. Silica may be any of amorphous silica or crystalline silica, or a mixture thereof may also be used. Particularly, amorphous (fused) silica is preferred. Furthermore, calcium carbonate may be any of natural heavy calcium carbonate or synthetic precipitated calcium carbonate.

Examples of the shape of such an inorganic filler include a spherical shape, a needle shape, a plate shape, a scaly shape, a hollow shape, an irregular shape, a hexagonal shape, a cubic shape, and a flaky shape. However, from the viewpoint of highly efficient filling of the inorganic filler, a spherical shape is preferred.

Furthermore, the average particle size of these inorganic fillers is preferably 0.1 μm to 25 μm. If the average particle size is less than 0.1 μm, the specific surface area is large, and dispersion failure occurs as a result of the influence of the aggregating action between filler particles. Furthermore, it becomes difficult to increase the filling amount of the filler. On the other hand, if the average particle size is greater than 25 μm, the hole-filling properties in hole parts in a printed wiring board becomes poor, and there is a problem that when a conductor layer is formed on a sagging part, smoothness deteriorates. The average particle size is more preferably 1 μm to 10 μm.

The mixing proportion of such an inorganic filler is preferably set to 45% to 90% by mass relative to the total amount of the thermosetting filling resin composition. If the mixing proportion is less than 45% by mass, heat expansion of the cured product thus obtainable occurs to an excessively large extent, and it is difficult to obtain sufficient abradability or adhesiveness. On the other hand, if the mixing proportion is greater than 90% by mass, preparation of a paste becomes difficult, and it is difficult to obtain good printability or good hole filling characteristics. The mixing proportion is more preferably 50% to 75% by mass.

The fatty acid is used in order to impart thixotropic properties to the thermosetting filling resin composition. If it is merely intended to impart thixotropic properties, it will be acceptable to add only an irregularly shaped filler such as organic bentonite or talc; however, in this case, the initial thixotropic properties are good, but the thixotropic properties over time deteriorate. The thermosetting filling resin composition of this embodiment utilizes low compatibility between this fatty acid and the epoxy resin, and as a result of the addition of a fatty acid, good thixotropic properties can be obtained, while a change in the thixotropic properties over time is suppressed, so that good thixotropic properties can be maintained.

The fatty acid in the thermosetting filling resin composition of the present embodiment is represented by formula: (R₁COO)n-R₂ (substituent R₁ represents a hydrocarbon having 5 or more carbon atoms; substituent R₂ represents hydrogen, a metal alkoxide, or a metal; and n=1 to 4). This fatty acid can exhibit a thixotropic properties imparting effect when the substituent R₁ has 5 or more carbon atoms. The fatty acid is more preferably such that n is 7 or greater.

The fatty acid may be an unsaturated fatty acid having a double bond or a triple bond in the carbon chain, or may be a saturated fatty acid that does not contain those. Examples thereof include stearic acid (the carbon number, the number of unsaturated bonds, and the number inside parentheses express numeral values based on the position. 18:0), hexanoic acid (6:0), oleic acid (18:1(9)), eicosanoic acid (20:0), docosanoic acid (22:0), and melissic acid (30:0). The carbon number of the substituent R1 of these fatty acids is preferably 5 to 30. More preferably, the substituent R1 has 5 to 20 carbon atoms. Furthermore, for example, the fatty acid may also be a fatty acid having a backbone structure with along (having 5 or more carbon atoms) aliphatic chain as the structure of the coupling agent system, such as a metal alkoxide having a titanate-based substituent capped with an alkoxy group as a substituent R2. For example, trade name: KR-TTS (manufactured by Ajinomoto Fine-Techno Co., Inc.) and the like can be used. In addition to those, metal soaps such as aluminum stearate and barium stearate (respectively manufactured by Kawamura Kasei Industry Co., Ltd.) can be used. Elements of other metal soaps include Ca, Zn, Li, Mg, and Na.

The mixing proportion of such a fatty acid is preferably set to 0.1 parts to 2 parts by mass relative to 100 parts by mass of the inorganic filler. If the mixing proportion is less than 0.1 parts by mass, sufficient thixotropic properties cannot be imparted, and when hole parts in a printed wiring board are filled, sagging is likely to occur. On the other hand, if the mixing proportion is greater than 2 parts by mass, the apparent viscosity of the thermosetting filling resin composition becomes excessively high, and the hole filling properties for hole parts in a printed wiring board are decreased. Furthermore, defoamability is deteriorated such that after the resin filler is filled in hole parts and cured, air bubbles remain inside the hole parts or the like, and thus voids or cracks are likely to occur. The mixing proportion is more preferably 0.1 parts to 1 part by mass.

The fatty acid may be incorporated by using an inorganic filler that has been surface-treated with a fatty acid in advance, and thus, thixotropic properties can be imparted more effectively to the thermosetting filling resin composition. In this case, the mixing proportion of the fatty acid can be more reduced than that in the case of using an untreated filler. When the entirety of the inorganic filler is used as a fatty acid-treated filler, the mixing proportion of the fatty acid is preferably set to 0.1 parts to 1 part by mass relative to 100 parts by mass of the inorganic filler.

Furthermore, for the thermosetting filling resin composition of the present embodiment, it is preferable to further use a silane-based coupling agent. When such a constitution is employed, the adhesiveness between the inorganic filler and the epoxy resin is enhanced, and the occurrence of cracks in a cured product of the filler can be suppressed.

Examples of the silane-based coupling agent include epoxysilane, vinylsilane, imidazolesilane, mercaptosilane, methacryloxysilane, aminosilane, styrylsilane, isocyanatosilane, sulfidosilane, and ureidosilane.

The mixing proportion of such a silane-based coupling agent is preferably set to 0.05 parts to 2.5 parts by mass relative to 100 parts by mass of the inorganic filler. If the mixing proportion is less than 0.05 parts by mass, sufficient adhesiveness cannot be obtained, and the occurrence of cracks is likely to be caused. On the other hand, if the mixing proportion is greater than 2.5 parts by mass, defoamability is deteriorated such that after the resin filler is filled in hole parts in a printed wiring board and cured, air bubbles remain inside the hole parts or the like, and thus voids or cracks are likely to occur.

The silane-based coupling agent may also be incorporated by using an inorganic filler that has been surface-treated with a silane-based coupling agent in advance.

In regard to the thermosetting filling resin composition of the present embodiment, when a liquid epoxy resin is used at room temperature, it is not necessary to use a diluting solvent; however, in order to adjust the viscosity of the composition, a diluting solvent may be added. Examples of the diluting solvent include organic solvents, such as ketones such as methyl ethyl ketone and cyclohexanone; aromatic hydrocarbons such as toluene, xylene and tetramethylbenzene; glycol ethers such as methylcellosolve, butylcellosolve, methylcarbitol, ethylcarbitol, butylcarbitol, propylene glycol monomethyl ether, dipropylene glycol monoethyl ether, and triethylene glycol monoethyl ether; esters such as ethyl acetate, butyl acetate, and acetic acid esterification products of the glycol ethers; alcohols such as ethanol, propanol, ethylene glycol and propylene glycol; aliphatic hydrocarbons such as octane and decane; and petroleum-based solvents such as petroleum ether, petroleum naphtha, hydrogenated petroleum naphtha, and solvent naphtha. These can be used singly, or two or more kinds can be used in combination.

The mixing proportion of the diluting solvent is preferably 10% by mass or less of the total amount of the thermosetting filling resin composition. If the mixing proportion of the diluting solvent is greater than 10% by mass, at the time of curing, bubbles or cracks are likely to occur in the hole parts under the influence of the evaporation of volatile components. The mixing proportion is more preferably 5% by mass or less.

In the thermosetting filling resin composition of the present embodiment, an oxazine compound containing an oxazine ring, which is obtained by causing a phenol compound to react with formalin and a primary amine, may also be incorporated additionally as necessary. When the filler contains an oxazine compound, when the thermosetting filling resin composition that has been filled in hole parts in a printed wiring board is cured, and then electroless plating is carried out over the cured product thus formed, roughening of the cured product by using an aqueous solution of potassium permanganate or the like is facilitated, and the peel strength to detach the cured product from the plating can be increased.

Furthermore, known colorants such as Phthalocyanine Blue, Phthalocyanine Green, Iodine Green, Disazo Yellow, Crystal violet, titanium oxide, carbon black, and naphthalene black, which are used in conventional resist inks for screen printing, may also be added.

Also, in order to impart storage stability at the time of storage, known thermal polymerization inhibitors such as hydroquinone, hydroquinone monomethyl ether, tert-butyl catechol, pyrogallol, and phenothiazine may be incorporated, and in order to adjust viscosity or the like, known thickening agents or thixotropic agents such as clay, kaolin, organic bentonite, and montmorillonite can be added. In addition, known additives, such as defoamants such as silicone-based, fluorine-based and polymer-based defoamants; leveling agents; and adhesiveness imparting agents such as imidazole-based, triazole-based and triazole-based agents, and silane coupling agents, can be incorporated.

For the thermosetting filling resin composition thus obtainable, the viscosity that is measured by using a rotary viscometer is preferably 200 Ps to 1000 Ps as a value measured under the conditions of 25° C., 5 rpm, and 30 seconds. If the viscosity is less than 200 Ps, it is difficult to maintain the shape, and sagging occurs. Also, if the viscosity is higher than 1000 Ps, the hole filling properties for hole parts in a printed wiring board are decreased. The viscosity is more preferably 200 Ps to 800 Ps.

The viscosity is measured with a cone-plate type viscometer composed of a cone rotor (conical rotor) and a plate as described in JIS 28803, for example, Model TV-30 (manufactured by Toki Sangyo Co., Ltd., rotor 3°×R9.7).

The thermosetting filling resin composition resin filler of the present embodiment is filled in hole parts in a printed wiring board in which, for example, an electroconductive layer of copper or the like is formed on the surfaces and the wall surfaces of the hole parts, by using a known patterning method such as a screen printing method, a roll coating method, or a die coating method. In this case, the thermosetting filling resin composition is fully filled such that the filler slightly protrudes from the hole parts. Subsequently, the printed wiring board in which the hole parts are filled with the thermosetting filling resin composition is heated, for example, at 150° C. for 60 minutes, and thereby the thermosetting filling resin composition is cured. Thus, a cured product is formed.

Then, unnecessary parts of the cured product that protrudes from the surface of the printed wiring board are removed by a known physical polishing method, and thus the cured product is flattened. The electroconductive layer at the surface is patterned into a predetermined pattern, and thus a predetermined circuit pattern is formed. Meanwhile, if necessary, an electroconductive layer may be formed on the cured product by means of electroless plating or the like, after the cured product is subjected to surface roughening by using an aqueous solution of potassium permanganate.

### EXAMPLES

Hereinafter, embodiments of the present invention will be specifically described by way of Examples and Comparative Examples. Meanwhile, the units “parts” and “percent (%)” described below are all on a mass basis, unless particularly stated otherwise.

### (Preparation of Paste)

Pastes of Examples 1 to 8 and Comparative Examples 1 to 3, which were thermosetting filling resin composition, were prepared by preliminarily mixing the components indicated in Table 1 in a stirrer at the respective mixing proportions (parts by mass), and then dispersing the mixture with a three-roll mill.

TABLE 1

| | | | | | | | | | Comparative | | |
|---|---|---|---|---|---|---|---|---|---|---|---|
| | Example | | | | | | | | Example | | |
| | 1 | 2 | 3 | 4 | 5 | 6 | 7 | 8 | 1 | 2 | 3 |
| Bis-A type liquid | 50 | | | | | 50 | 50 | 50 | 50 | 50 | 25 |
| epoxy resin *1 | | | | | | | | | | | |
| Bis-F type liquid | 50 | | | | | 50 | 50 | 50 | 50 | 50 | 25 |
| epoxy resin *2 | | | | | | | | | | | |
| Amine type epoxy *3 | | 100 | 100 | 100 | 100 | | | | | | 50 |
| Imidazole *4 | 7 | 7 | 7 | 7 | 7 | 7 | 7 | 7 | 7 | 7 | 7 |
| Spherical silica | | | | 300 | 300 | 150 | | | | | 130 |
| D50 = 0.5 μm *5 | | | | | | | | | | | |
| Heavy calcium | 130 | | 99 | | | | 150 | 150 | 130 | 130 | |
| carbonate D50 = 2.3 μm *6 | | | | | | | | | | | |
| Heavy calcium | | | | | | | | | 20 | | |
| carbonate D50 = 1.2 μm *7 | | | | | | | | | | | |
| Heavy calcium | 20 | 110 | 11 | 33 | 33 | | | | | | |
| carbonate fatty | | | | | | | | | | | |
| acid 1% *8 | | | | | | | | | | | |
| Titanate-based | | | | | | 0.2 | | | | | |
| coupling agent *9 | | | | | | | | | | | |
| Hexanoic acid *10 | | | | | | | 0.2 | | | | |
| Stearic acid *11 | | | | | | | | 0.2 | | | |
| Silane coupling | 1.3 | 1.3 | | 3 | 6 | 1.3 | 1.3 | 1.3 | 1.3 | 1.3 | 1.3 |
| agent *12 | | | | | | | | | | | |
| Organic | | | | | | | | | | 20 | |
| bentonite *13 | | | | | | | | | | | |
| Talc *14 | | | | | | | | | | | 20 |
| Σ | 258.3 | 218.3 | 217 | 443 | 446 | 258.5 | 258.5 | 258.5 | 258.3 | 258.3 | 258.3 |
| Filler content | 58.1 | 50.4 | 50.7 | 75.2 | 75.9 | 58.0 | 58.0 | 58.0 | 58.1 | 58.1 | 58.1 |
| (wt %) | | | | | | | | | | | |
| Amount of fatty acid | 0.13 | 1 | 0.1 | 0.1 | 0.1 | 0.1 | 0.13 | 0.13 | 0 | — | — |
| treatment | | | | | | | | | | | |
| (relative to | | | | | | | | | | | |
| filler, wt %) | | | | | | | | | | | |
| Epoxysilane | 1 | 0 | 0 | 1 | 2 | 1 | 1 | 1 | 1 | 1 | 1 |
| treatment | | | | | | | | | | | |
| (relative to | | | | | | | | | | | |
| filler, wt %) | | | | | | | | | | | |

*1: 828 (manufactured by Mitsubishi Chemical Corp.)
*2: 807 (manufactured by Mitsubishi Chemical Corp.)
*3: Para-aminophenol type epoxy jER-630 (manufactured by Mitsubishi Chemical Corp.)
*4: 2MZ-A (manufactured by Shikoku Chemical Corp.)
*5: SO-C5 (manufactured by Admatechs Co., Ltd.)
*6: Softon 1800 (manufactured by Bihoku Funka Kogyo Co., Ltd.)
*7: Micropowder 3N (manufactured by Bihoku Funka Kogyo Co., Ltd.)
*8: Micropowder 3S (manufactured by Bihoku Funka Kogyo Co., Ltd.; 1 wt % fatty acid surface treatment relative to the mass of Micropowder 3N)
*9: Fatty acid backbone-containing KR-TTS (manufactured by Ajinomoto Fine-Techno Co., Inc.)
*10: Reagent grade (manufactured by Sigma-Aldrich Co.)
*11: Reagent grade (manufactured by Sigma-Aldrich Co.)
*12: Trimethoxyepoxysilane KBM-403 (manufactured by Shin-Etsu Chemical Co., Ltd.)
*13: Hydrous aluminum silicate organic composite (manufactured by Shiraishi Kogyo Kaisha, Ltd.)
*14: Hi-Filler talc (hydrous magnesium silicate) Spectra K (manufactured by Matsumura Sangyo Co., Ltd.)
*14: Hi-Filler talc (hydrous magnesium silicate) Spectra K (manufactured by Matsumura Sangyo Co., Ltd.)

### (Aging of Paste)

Since the pastes thus obtained were single-liquid pastes, the pastes had to be actually stored under refrigeration. However, in order to evaluate changes over time by an acceleration test, each of the pastes was aged (heating treatment), and various aged pastes were obtained. The aging conditions were such that the pastes were maintained at 40° C. for 3 days in a constant temperature chamber (IN-800 manufactured by Yamato Scientific Co., Ltd.)

### <Evaluation of Deterioration of Thixotropic Properties Over Time>

For each of the aged pastes, viscosity: η₅ and η₅₀ were measured at 25° C. by using a cone-plate type viscometer (TV-30 manufactured by Toki Sangyo Co., Ltd.) at a speed of rotation of 5 rpm and 50 rpm.

Furthermore, the thixotropy index (TI=η₅/η₅₀) was determined from the viscosities thus obtained. The values of η₅ and TI for the various pastes of Examples are presented in Table 2.

As indicated in Table 2, in Examples 1 to 8, good values of the viscosity after aging and the TI were obtained. On the other hand, in Comparative Examples 1 to 3 where no fatty acid was added, the TI value was 1.6 or less. Thus, it can be seen that sufficient thixotropic properties cannot be obtained due to deterioration over time.

### (Production of Hole-Filled Substrate)

Hole parts of printed wiring boards were filled by using the various pastes and the various aged pastes thus obtained.

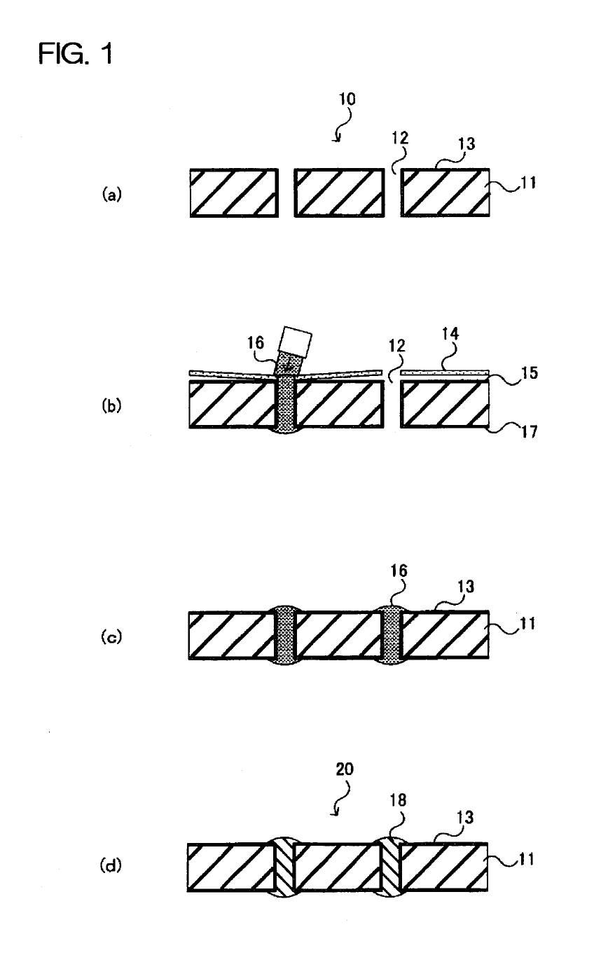

FIG. 1 presents a process diagram. As indicated in FIG. 1(a), a printed wiring board (both-sided board) 10 (MCL-E-67, manufactured by Hitachi Chemical Co., Ltd.), in which through-holes 12 are formed as hole parts in a base material 11, and an electroconductive layer 13 is formed on the surfaces and the through-hole wall surfaces, was used, and the printed wiring board was subjected to an acid treatment (washing) using a 1% aqueous hydrochloric acid solution, as a pretreatment.

The printed wiring board was a both-sided substrate with specifications such as thickness: 1.6 mm, through-hole diameter: 0.25 mm, through-hole pitch: 1 mm, number of through-holes: 400 holes, and there was no pattern formation.

Then, as indicated in FIG. 1(b), a semi-automated screen printing machine (SSA-PC560A, manufactured by Tokai Shoji Co., Ltd.) was used, and dot pattern printing was carried out by disposing a screen mesh 14 on a surface to be printed 15, and supplying a paste 16 thereto. As indicated in FIG. 1(c), the paste 16 was filled in the through-holes 12. At this time, if necessary, the amount of paste protruding from an extruded surface 17 was adjusted to be constant for the various pastes.

Subsequently, as indicated in FIG. 1(d), each of the printed wiring boards respectively filled with the various pastes was introduced into a hot air circulating drying furnace (DF610, manufactured by Yamato Scientific Co., Ltd.), and the printed wiring board was subjected to a curing treatment at 150° C. for 60 minutes. Thus, a hole-filled substrate 20 in which the through-holes 12 are filled with a cured product 18 was formed.

The hole-filled substrates 20 formed in this manner were evaluated as follows.

### <Evaluation of Sagging and Spreading>

For the various hole-filled substrates 20 formed by using the various pastes and various aged pastes thus obtained, the state of the paste on the extruded surface side was observed in connection with sagging and spreading of the paste, by visual inspection and by using an optical microscope.

The results for a visual inspection evaluation of Examples and Comparative Examples are presented in Table 2. The evaluation criteria are as follows.

◯: A neat hemispherical shape was retained.

Δ: The shape of the paste was less round, but the pastes in adjacent through-holes were not in contact with each other.

x: Sagging and spreading of the paste were recognized, and pastes in adjacent through-holes were in contact with each other.

As indicated in Table 2, it can be seen that Examples 1 to 8 have no practical problem even after aging, and the paste shape can be retained.

### <Evaluation of Voids and Cracks>

For the various hole-filled substrates 20 thus obtained by using the various aged pastes, the cross-sections of the hole parts were observed with an optical microscope. The number of observed holes was set to 50 holes for each of the hole-filled substrates 20.

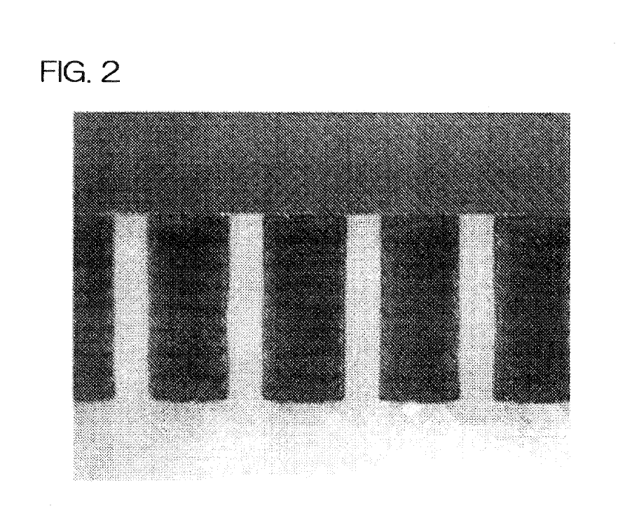

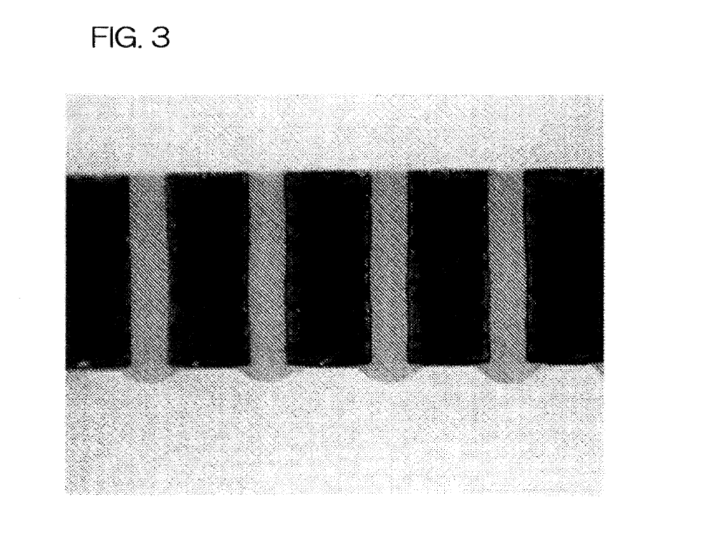

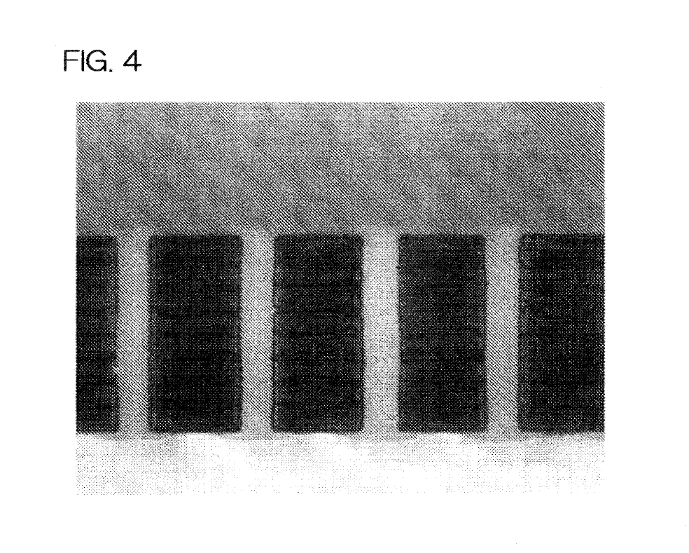

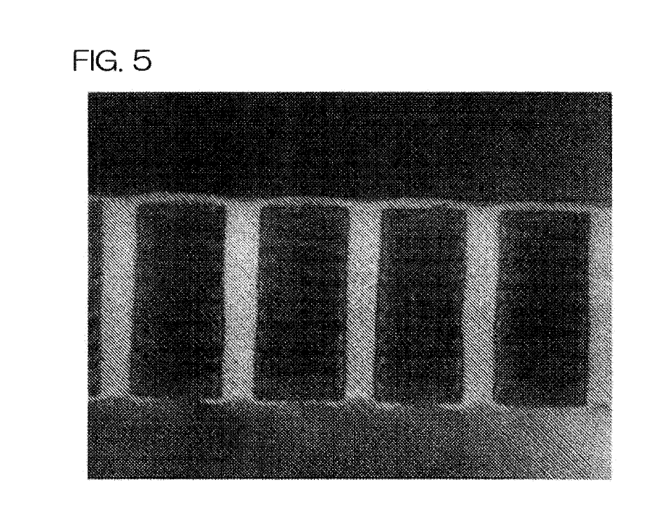

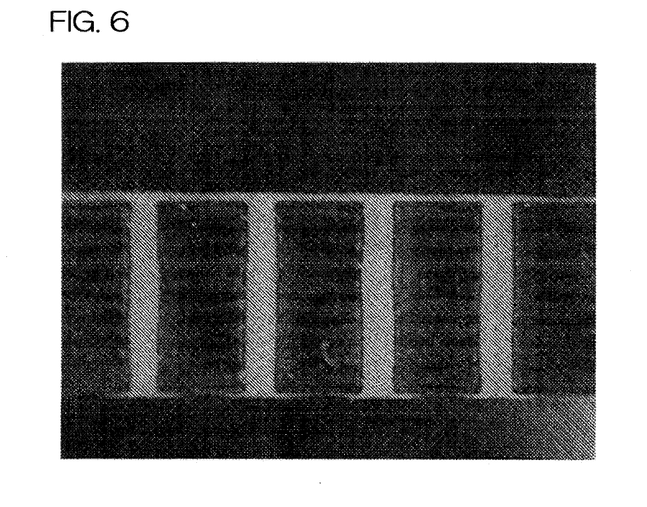

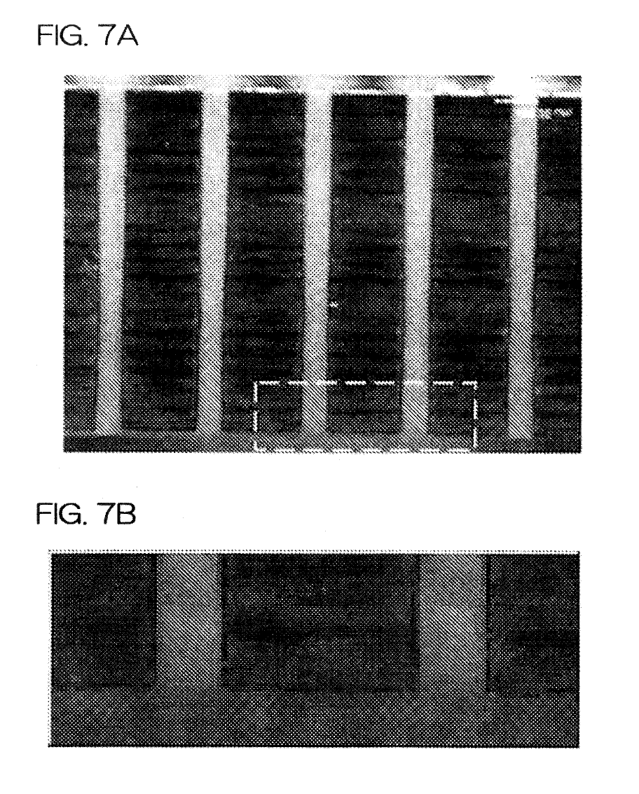

FIGS. 2 to 6 and FIG. 7A present optical microscopic photographs of Examples 2, 3 and 4 and Comparative Examples 1, 2 and 3, while FIG. 7B presents a partially magnified photograph of FIG. 7A. Meanwhile, Examples 1, 6, 7 and 8 were in the same state as that of Example 2.

Furthermore, the evaluation results for the Examples and Comparative Examples are presented in Table 2. The evaluation criteria are as follows.

◯: Air bubbles, cracks or voids were not recognized in all the through-holes.

x: Any one of air bubbles, cracks and voids is recognized.

Meanwhile, even when unaged pastes were used, the same results as those obtained with aged pastes were obtained.

As indicated in Table 2, it can be seen that Examples 1 to 8 have good cross-sectional shapes where voids, cracks or the like were not recognized.

### (Production of Polished Substrate)

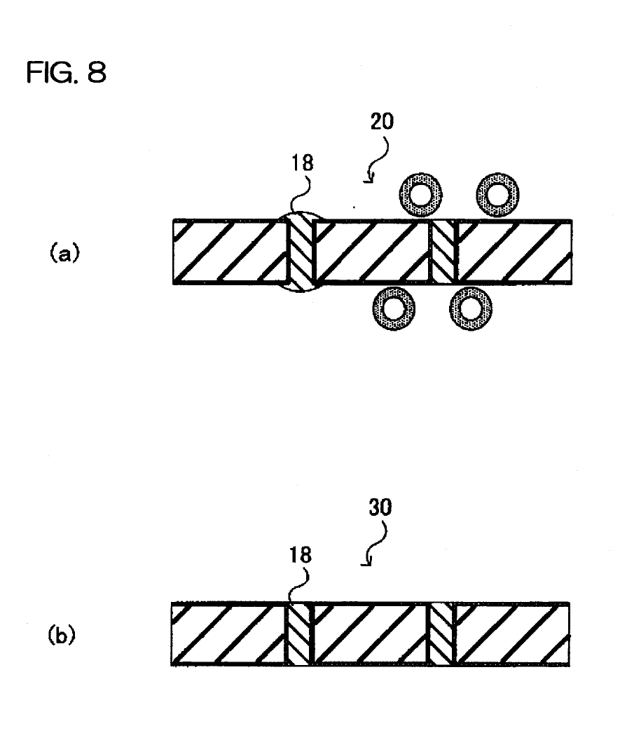

For each of the hole-filled substrates 20 formed by using the various aged pastes thus obtained, as indicated in FIG. 8(a), the cured product 17 of the paste that protruded from the through-holes 12 was polished once by using a buff polishing machine (manual biaxial polishing machine, manufactured by Seiko Electric Co., Ltd.) equipped with high-cut buffs 19 (SFBR-#320, manufactured by Sumitomo 3M, Ltd.) in 4 axes in total, with two axes per one surface on the top surface and the back surface. Thus, a polished substrate 30 as illustrated in, for example, FIG. 8(b) was obtained.

### <Evaluation of Abradability>

For each of the polished substrates thus obtained, the polish state of the surfaces was observed by visual inspection and by using an optical microscope. The evaluation results for the Examples and Comparative Examples are presented in Table 2. The evaluation criteria are as follows.

◯: The paste protruding from the surface was removed by polishing.

x: Residues of the paste were recognized around the through-holes and between adjacent through-holes.

As indicated in Table 2, it can be seen that Examples 1 to 8 exhibit good abradability even after aging.

TABLE 2

| | | | | | | | | | | Comparative | | |
|---|---|---|---|---|---|---|---|---|---|---|---|---|
| | | Example | | | | | | | | Example | | |
| | | 1 | 2 | 3 | 4 | 5 | 6 | 7 | 8 | 1 | 2 | 3 |
| Evaluation | Viscosity | 500 | 386 | 210 | 688 | 527 | 520 | 510 | 520 | 480 | 650 | 700 |
| of | [Ps] | | | | | | | | | | | |
| deterioration | TI value | 2.5 | 3.7 | 2.4 | 2.8 | 2.5 | 2.5 | 2.3 | 2.4 | 1.4 | 1.6 | 1.5 |
| in thixotropic | | | | | | | | | | | | |
| properties | | | | | | | | | | | | |
| over time | | | | | | | | | | | | |
| Evaluation of | Unaged | ◯ | ◯ | ◯ | Δ | Δ | ◯ | ◯ | ◯ | ◯ | ◯ | ◯ |
| sagging and | After | ◯ | ◯ | ◯ | Δ | Δ | ◯ | ◯ | ◯ | X | X | X |
| spreading | aging | | | | | | | | | | | |

| | | | | | | | | | | | |
|---|---|---|---|---|---|---|---|---|---|---|---|
| Evaluation of voids and | ◯ | ◯ | ◯ | ◯ | ◯ | ◯ | ◯ | ◯ | ◯ | ◯ | ◯ |
| cracks | | | | | | | | | | | |
| Evaluation of abradability | ◯ | ◯ | ◯ | ◯ | ◯ | ◯ | ◯ | ◯ | X | X | X |

As such, in Comparative Examples 1 to 3 in which no fatty acid was added, deterioration of the thixotropic properties of the pastes over time was significant, and sagging and spreading occurred. Also, abradability decreased, and also, voids, cracks and the like which would be directed to a decrease in reliability occurred in the cured products.

On the other hand, it can be seen that in Examples 1 to 8, deterioration of the thixotropic properties of the pastes over time was suppressed, and after filling in hole parts of the printed wiring boards and curing, good shape retentivity and abradability were obtained.

### REFERENCE SIGNS LIST

10 PRINTED WIRING BOARD
11 BASE MATERIAL
12 THROUGH-HOLE
13 ELECTROCONDUCTIVE LAYER
14 SCREEN MESH
15 PRINTED SURFACE
16 PASTE
17 EXTRUDED SURFACE
18 CURED PRODUCT
19 HIGH CUT BUFF
20 HOLE-FILLED SUBSTRATE
30 POLISHED SUBSTRATE

1-5. (canceled)

6. A thermosetting filling resin composition comprising an epoxy resin, an epoxy resin curing agent, an inorganic filler, and a fatty acid represented by formula:
(R₁COO)n-R₂
wherein substituent R₁ represents a hydrocarbon having 5 or more carbon atoms; substituent R₂ represents hydrogen, a metal alkoxide, or a metal; and n=1 to 4.

7. The thermosetting filling resin composition according to claim 6, wherein the fatty acid is incorporated in an amount of 0.1 parts to 2 parts by mass relative to 100 parts by mass of the inorganic filler.

8. The thermosetting filling resin composition according to claim 7, further comprising a silane-based coupling agent.

9. A printed wiring board comprising hole parts that are filled with a cured product of the thermosetting filling resin composition according to claim 6.

10. A printed wiring board comprising hole parts that are filled with a cured product of the thermosetting filling resin composition according to claim 7.

11. A printed wiring board comprising hole parts that are filled with a cured product of the thermosetting filling resin composition filler according to claim 8.

12. A thermosetting filling resin composition comprising an epoxy resin, an epoxy resin curing agent, an inorganic filler, a silane-based coupling agent, and a fatty acid represented by formula:
(R₁COO)n-R₂
wherein substituent R₁ represents a hydrocarbon having 5 or more carbon atoms; substituent R₂ represents hydrogen, a metal alkoxide, or a metal; and n=1 to 4.

13. A printed wiring board comprising hole parts that are filled with a cured product of the thermosetting filling resin composition according to claim 12.

14. A thermosetting filling resin composition comprising an epoxy resin, an epoxy resin curing agent, and an inorganic filler that has been surface-treated with a fatty acid represented by formula:
(R₁COO)n-R₂
wherein substituent R₁ represents a hydrocarbon having 5 or more carbon atoms; substituent R₂ represents hydrogen, a metal alkoxide, or a metal; and n=1 to 4.

15. The thermosetting filling resin composition according to claim 14, further comprising a silane-based coupling agent.

16. A printed wiring board comprising hole parts that are filled with a cured product of the thermosetting filling resin composition according to claim 14.

17. A printed wiring board comprising hole parts that are filled with a cured product of the thermosetting filling resin composition according to claim 15.
